(19) United States
(12) Patent Application Publication
(10) Pub. No.: US 2025/0040109 A1
(43) Pub. Date: Jan. 30, 2025

(54) SYSTEMS AND METHODS FOR REGULATING CURRENT FLOW THROUGH TWO OR MORE INVERTERS

(71) Applicant: The ESAB Group, Inc., North Bethesda, MD (US)

(72) Inventor: Wilson Alexander Schreiber, Lebanon, NH (US)

(21) Appl. No.: 18/357,344

(22) Filed: Jul. 24, 2023

(51) Int. Cl. H05K 7/20; H02M 1/00; H02M 7/537; H05H 1/28; H05H 1/36

(52) U.S. Cl. CPC H05K 7/20927; H02M 1/0009; H02M 1/0067; H02M 7/537; H05H 1/28; H05H 1/36; H05K 7/20209; H05K 7/20254; H05K 7/20263; H05K 7/20272

(57) ABSTRACT

Systems and methods for lessening temperature differences between first and second IGBTs respectively residing in first and second inverters, the first and second inverters being configured to collectively deliver current to an electrode of a torch for the purpose of producing a plasma arc. According to one method, the temperature of each of the first and second IGBTs is measured and the flow of current through one or more of the first and second inverters is altered based on the measured temperatures. The regulating of current flow through the first and second inverters is also based on a current request signal that is indicative of an amount of current requested to be delivered to the electrode. The lessening of temperature differences between the first and second IGBTs can additionally be based on current signals indicative of the current measured at the output of each of the first and second inverters.

### FIELD

This application relates to systems and methods for regulating current flow through two or more inverters that supply power to an electrode of a plasma cutting torch. Each of the inverters includes one or more insulated gate bipolar transistors. More particularly, this application relates to lessening/reducing temperature differences between the insulated gate bipolar transistors located in the different inverters while current produced by the two or more inverters is being delivered to the plasma torch electrode.

### BACKGROUND

Insulated gate bipolar transistors (IGBTs) are used in power supply inverters to rectify alternating current (AC) current to direct current (DC) at very high switching rates. Inverters employing IGBTs are widely known and used in the field of plasma torches for the purpose of delivery power to an electrode of a plasma torch. For this reason, the manner in which the IGBTs function in inverters will not be discussed herein.

A general configuration of an IGBT is illustrated in FIG. 1. The IGBT 10 includes a collector terminal 11, an emitter terminal 12, and a control terminal (i.e. gate terminal) 13. The IGBT is a multilayer device that includes a P body region 14, an N-drift region 15, a N+ buffer 16 and P+ substrate. As shown schematically in FIG. 1, an IGBT typically includes a casing 20 to which the IGBT structure (as described above) is thermally coupled. This allows the junction temperature of the IGBT to be controlled by transferring heat through the cover 20 to a cooling plate to which the cover is thermally coupled.

Plasma cutting operations involve the generation of a plasma arc at an end of a plasma torch. The general features of a plasma torch are discussed below. During torch operation, the inverters of the power supply are used to direct current to the torch electrode through the IGBTs to produce the plasma arc. For various reasons, while a torch is operated the junction temperature among the IGBTs located in different inverters can vary. (The junction temperature as used herein is a temperature anywhere in the afore-described multilayer device.) During operation, the temperatures of at least one IGBT per inverter is monitored and when a temperature of one or more of the IGBTs in the various inverters is detected to have reached or exceeded a threshold amount, all the inverters are thermally tripped (shut-down). In some cases this occurs while one or more IGBTs in one inverter still have a good deal of thermal overhead before they reach a thermal trip condition.

What is needed are systems and methods for minimizing temperature differences among IGBTs of different inverters to minimize the occurrence of thermal trips during plasma torch operation.

### SUMMARY

Disclosed herein are systems and methods for lessening/reducing temperature differences among IGBTs located in different inverters to minimize the occurrence of thermal trips during plasma torch operation. Thus, when a thermal trip condition occurs, it is when most or all of the IGBTs of all the inverters are approaching or have reached a threshold trip temperature.

According some implementations, a system is provided that includes a power supply system in which two or more inverters are configured to deliver current to an electrode of a plasma torch. The IGBT or IGBTs of each inverter may be thermally coupled to a cooling plate that is cooled by a fluid flowing therethrough. Example systems for cooling the IGBTs are discussed in more detail below.

According to one aspect, current is delivered to a torch electrode through the use of at least first and second inverters that each includes one or more IGBTs. According to one implementation, the temperatures of at least one IGBT in each of the first and second inverters is measured, and thereafter the flow of current through at least one of the first and second inverters is altered based on the differences in the measured temperatures of the IGBTs. The flow of current is regulated to reduce differences in temperature of the IGBTs residing in the different inverters. The regulating of current flow through the first and second inverters is also based on a current request signal that is indicative of an amount of current requested to be delivered to the electrode. The lessening of temperature differences between the IGBTs in the different first and second inverters can additionally be based on current signals indicative of the current measured at the output of each of the inverters.

According to one implementation at least first and second inverters are collectively configured to deliver current to an electrode of a torch for the purpose of producing a plasma arc. A power control system associated with the first and second inverters is configured to regulate a first flow of current through the first inverter and to regulate a second flow of current through the second inverter based on respective first and second sensed temperatures of the first and second IGBTs respectively forming a part of the first and second inverters. According to some implementations, the temperature sensing is performed by first and second temperature sensors (e.g. thermocouples, thermistors, etc.) that are respectively attached to or coupled to a part (e.g., casing, lug, etc.) of the first and second IGBTs. Because the junction temperature of an IGBT is critical to its operation, a correlation between the sensed casing temperature and the junction temperature of an IGBT may be used to determine the junction temperature with reasonable accuracy.

The first and second flows of current are also regulated based on the current request signal as discussed above. According to some implementations a controller is configured to receive the current request signal, a first temperature signal indicative of the first sensed temperature, and a second temperature signal indicative of the second sensed temperature, and based on the received signals, to regulate the first flow of current and the second flow of current to lessen a difference between the first sensed temperature and the second sensed temperature while the first and second flows of current are being respectively delivered through the first and second inverters. For example, when the second sensed temperature is greater than the first sensed temperature, the controller may be configured to increase the first flow of current through the first inverter and/or decrease the second flow of current through the second inverter.

According to some implementations, the system further includes first and second current sensors that are respectively configured to produce first and second current signals indicative of first and second currents produced by the first and second inverters. In such implementations, the controller is configured to receive the first and second current signals and to regulate the first flow of current through the first inverter and the second flow of current through the second inverter based in part on the first current signal and the second current signal.

As noted above, the first and second IGBTs may be respectively thermally coupled to first and second cooling plates that are thermally coupled to tubing through which a fluid is configured to flow to respectively cool the first and second IGBTs. The cooling system in which the cooling plates are comprised typically includes a heat exchanger through which the fluid flows for the purpose of being cooled. The heat exchanger has a fluid outlet through which the fluid is delivered to the tubing. According to some implementations, the first and second cooling plates are disposed in series with the second cooling plate being located downstream the first cooling plate. Under such circumstances, the fluid entering the first cooling plate is cooler than the fluid entering the second cooling plate. As can be appreciated, the in series relationship of the first and second cooling plates at least in part contributes to junction temperature differences between the first and second IGBTs. The systems and methods disclosed herein are intended to resolve this issue at least partially by managing current flows through the inverters. This issue can also be resolved at least partially by arranging the cooling plates of the IGBTs in parallel so that the temperature of the cooling fluid entering each of the cooling plates is substantially the same.

A method for delivering current to an electrode of a torch is provided that uses at least first and second inverters that each comprises one or more IGBTs. According to some implementations the method includes:
(a) using a first temperature sensor to sense a temperature of a first IGBT of the first inverter and producing a first temperature signal indicative of the temperature of the first IGBT;
(b) using a second temperature sensor to sense a temperature of a second IGBT of the second inverter and producing a second temperature signal indicative of the temperature of the second IGBT;
(c) receiving a current request signal indicative of an amount of current requested to be delivered to the electrode;
(d) regulating a first flow of current through the first inverter and regulating a second flow of current through the second inverter based on the respective first and second temperature signals and the current request signal;
(e) using the first and second temperature signals and the current request signal, regulating one or both of the first flow of current and the second flow of current to lessen a difference between the temperature of the first IGBT and the temperature of the second IGBT while the first and second flow of current are being respectively delivered through the first and second inverters.

The method for delivering current to an electrode may further include:
(a) using a first current sensor to sense a current produced by the first inverter and to produce a first current signal indicative of the current produced by the first inverter;
(b) using a second current sensor to sense a current produced by the second IGBT and to produce a second current signal indicative of the current produced by the second inverter; and
(c) regulating one or both of the first flow of current through the first inverter and the second flow of current through the second inverter using the first current signal and the second current signal.

According to some implementation the cooling system includes means for cooling both the torch electrode and the cooling plates of the IGBTs. According to one implementation the casings of the IGBTs are thermally coupled to their respective cooling plates and the cooling plates are cooled by a fluid that flows through tubing thermally coupled to the cooling plates. As explained above, the cooling plates may be arranged in series or in parallel. The cooling system also includes a tank in which the fluid is stored. A pump is located downstream the tank and is configured to circulate the fluid through the cooling system so that when the fluid exits the pump, the fluid sequentially flows through an electrode cooling channel of the torch, the heat exchanger and the tubing of the cooling plates. The fluid exits the cooling plates and is directed into an inlet of the tank. Hence, when the pump is operating, the fluid recirculates through the tank.

According to some implementations the heat exchanger is a radiator having a cooling fan that forces air over the radiator coils that carry the fluid. According to some implementations, the fan is driven by an electric motor and the controller is configured to turn the fan motor on and off based on the sensed temperatures of the IGBTs. According to some implementations, the fan is driven by a variable speed electric motor and the controller is configured alter the speed of the fan motor based on the sensed temperatures of the IGBTs.

According to some implementations, the pump is driven by an electric motor and the controller is configured to turn the pump motor on and off based on the sensed temperatures of the IGBTs. According to some implementations, the pump is driven by a variable speed electric motor and the controller is configured alter the speed of the pump motor based on the sensed temperatures of the IGBTs.

The junction temperatures of the IGBTs residing in different inverters may be managed using any one of the systems and methods disclosed above or below, or any combination thereof.

These and other advantages and features will become apparent in view of the figures and detailed description.

### BRIEF DESCRIPTION OF THE DRAWINGS

FIG. 1 is a schematic of an IGBT according to one implementation.

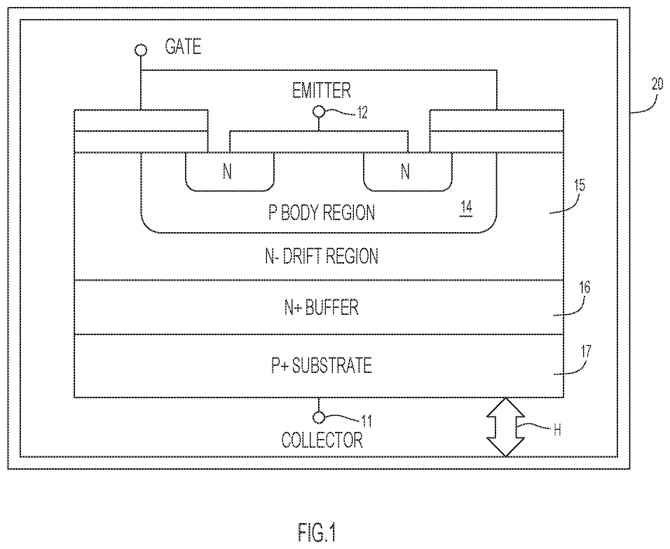

FIG. 2 is a control diagram for regulating current flows through multiple inverters for the purpose of lessening differences between the junction temperatures of IGBTs residing in different inverters.

FIG. 3 illustrates a controller that is configured for use in regulating current flows through multiple inverters based on a current request signal and temperature signals indicative of the temperatures of IGBTs residing in different inverters.

FIG. 4 illustrates a controller that is configured for use in regulating current flows through multiple inverters based on a current request signal, current signals indicative of the current flowing through the multiple inverters and temperature signals indicative of the temperatures of the IGBTs residing in different inverters.

FIG. 5 illustrates a controller like that of FIG. 3 that is further configured to regulate power to a radiator fan motor and/or to regulate power to a fluid pump motor in response to the temperature signals.

FIG. 6 is a schematic of a cooling system according to one implementation wherein the cooling plates are arranged in series.

FIG. 7 is a schematic of a cooling system according to one implementation wherein the cooling plates are arranged in parallel.

FIG. 8 is a side view of an IGBT thermally coupled to a cooling plate according to one implementation.

FIG. 9 illustrates an end of a plasma torch that includes a cooling channel through which fluid flows to cool the torch electrode.

FIG. 10 is a flow chart of a method for regulating currents through multiple inverters according to one implementation.

FIG. 11 is a flow chart of a method for regulating currents through multiple inverters according to another implementation.

### DETAILED DESCRIPTION

For discussion purposes, the disclosure that follows is primarily directed to plasma cutting torches, but is nonetheless applicable to welding torches and to other types of cutting torches in which current is delivered by multiple inverters that each comprises one or more IGBTs.

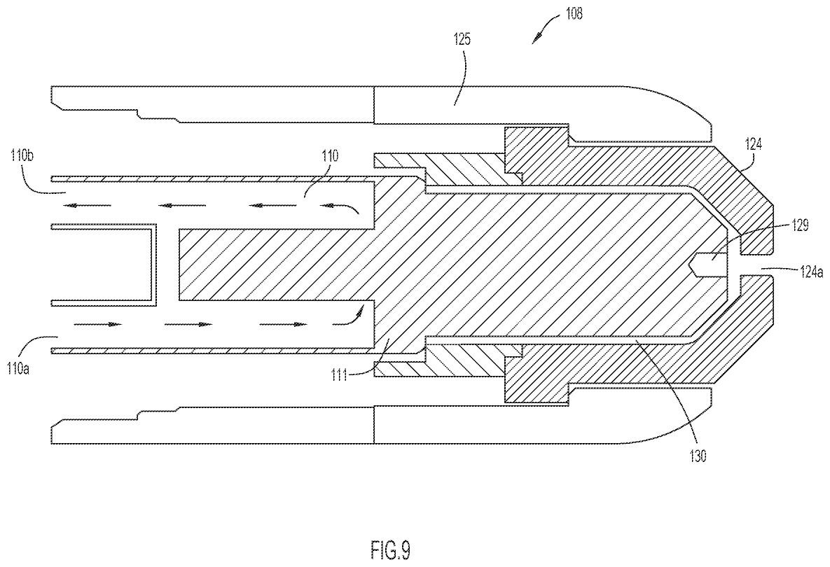

FIG. 9 is a generic illustration of a distal end portion of a plasma torch 108 according to one implementation. For simplicity, FIG. 9 illustrates the torch 108 without various components or parts, such as power or gas transfer components, that are typically included in a plasma cutting torch. Instead, FIG. 9 only illustrates select components or parts that allow for a clear and concise understanding of the systems and methods disclosed herein. In the depicted implementation, the torch 108 includes a number of parts, such as, for example, the electrode 111, a nozzle 124 and a shield cup 125. A distal-most end of the nozzle 124 includes an orifice 124a. Located in a distal end portion of the electrode 111 is an emitter 129.

In use, the plasma torch 108 is configured to emit a plasma arc between the electrode 111 and a workpiece to which a grounding clamp is typically attached. As shown in FIG. 9, the torch tip 124 is spaced a distance away from the electrode 111 with there being a process gas flow channel 130 disposed between them. During initiation, current is first supplied by inverters 201a, 201b, 201c to the nozzle 124 (anode) to generate an arc between the nozzle 124 and the electrode 111 (cathode) across the process gas flow channel 130. As process gas flows through channel 130 during arc initiation it is ionized to form an electrically conductive plasma that is then directed out the orifice 124a of the nozzle 124 towards an electrically conductive workpiece (not shown). Once this occurs, power is transferred to the electrode 111 with current being delivered to the electrode through the inverters. This establishes an electrical circuit between the power source and the ground to which the workpiece is coupled. A plasma arc that closes the electrical circuit is thus established between the electrode 111 and the workpiece, the plasma arc being sufficient to cut through the workpiece by a localized melting of the material from which the workpiece is made. When power is supplied to the electrode 111, power to the nozzle 124 is terminated. When a cut, piercing or marking operation is complete, the plasma arc is extinguished by terminating current flow from the inverters 201a, 201b, 201c to the electrode 111.

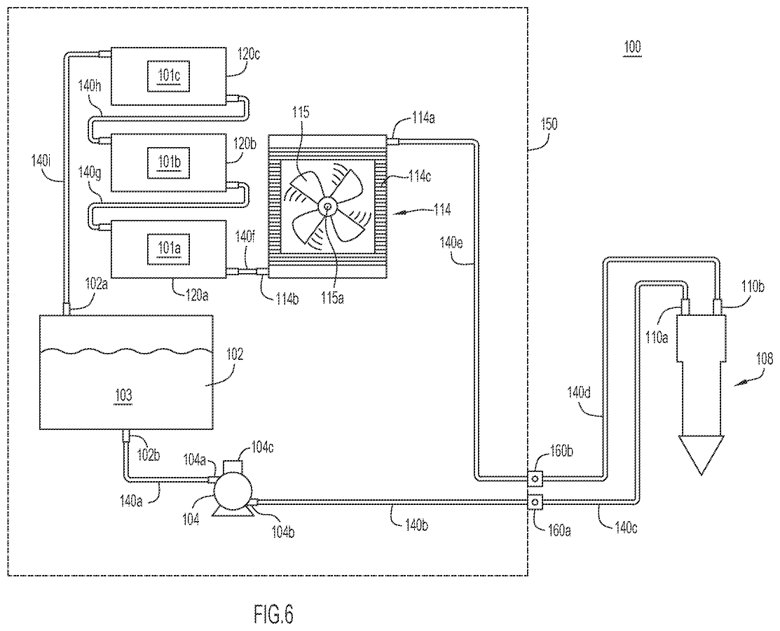

The junction temperature of an IGBT must be maintained below a maximum value in order to ensure proper and sustained operation. FIG. 6 illustrates an example cooling system 100 in which a fluid is circulated to cool the torch electrode and the IGBTs 101a, 101b and 101c respectively associated with inverters 201a, 201b and 201c. As explained above, the inverters are configured to deliver current to the electrode 111 of the plasma torch 108. In the examples disclosed herein, three inverters are used to deliver power to the torch electrode. However, it is appreciated that as few of two or greater than three inverters may be used.

In the example system of FIG. 6, the three IGBTs 101a, 101b, 101c are respectively thermally coupled to cooling plates 120a, 120b, 120c. In the system of FIG. 6, each inverter is shown having a single IGBT. It is appreciated, however, that each of the inverters may possess multiple IGBTs that are collectively controlled to produce a current at an output of the inverter. In instances where an inverter comprises multiple IGBTs, the IGBTs of that inverter may be thermally coupled to a common cooling plate.

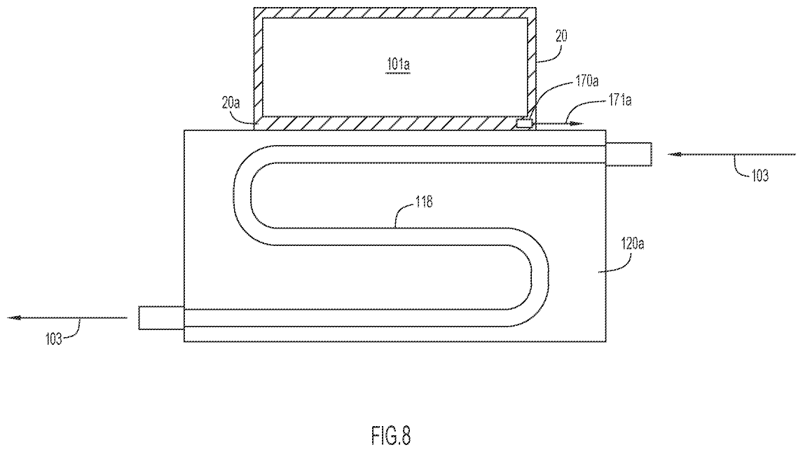

As shown in FIG. 8, according to some implementations the cooling plates are thermally coupled to tubing 118 (attached to or embedded therein) through which a fluid 103 flows after having passed through a heat exchanger 114. FIG. 8 illustrates the cooling plate 120a to which IGBT 101a is thermally coupled. As shown in FIG. 8, a thermally conductive bottom portion 20a of the IGBT casing 20 is thermally coupled to the cooling plate 120. Although not shown in FIG. 8, a thermally conductive grease or any other highly thermally conductive material may be disposed between the casing portion 20a and the cooling plate 120a to enhance heat transfer. IGBTs 101b and 101c may be similarly coupled to their respecting cooling plates 120b and 120c. As will be discussed in more detail below, according to some implementations the temperatures of the IGBTs 101a, 101b, 101c are respectively monitored by a temperature sensors 170a, 170b and 170c that is each configured to produce a temperature signal 171a, 171b and 171b indicative of the sensed IGBT temperature.

Turning again to FIG. 6, the system includes a fluid circuit that includes a tank 102 for storing the fluid 103, the tank having a fluid inlet 102a and a fluid outlet 102b. According to some implementations the fluid is water or a water glycol solution. Located downstream and in fluid communication with the fluid outlet 102b of the tank 102 is a pump 104 that is configured to produce a pressurized fluid flow at the pump outlet 104b. The pump outlet 104b is located upstream and in fluid communication with an inlet 110a of a cooling channel 110 located inside a plasma torch 108. The cooling channel 110 is arranged to put the fluid 103 in contact with at least a portion of the electrode 111 for the purpose of cooling the electrode at least when the torch is in use.

The heat exchanger 114 is configured to cool the fluid 103 before the fluid is delivered to the cooling plates 120a, 120b, 120c through tubing 118. The heat exchanger 114 has a fluid inlet 114a that is located downstream and in fluid communication with an outlet 110b of the torch cooling channel 110. The tubing 118 is located downstream and in fluid communication with the fluid outlet 114b of the heat exchanger.

To complete the circuit, the tank inlet 102a is located downstream and in fluid communication with the tubing 118 through fluid conduit 140i. In the example of FIG. 6, multiple fluid conduits 140a-i are used to connect the various fluid circuit components.

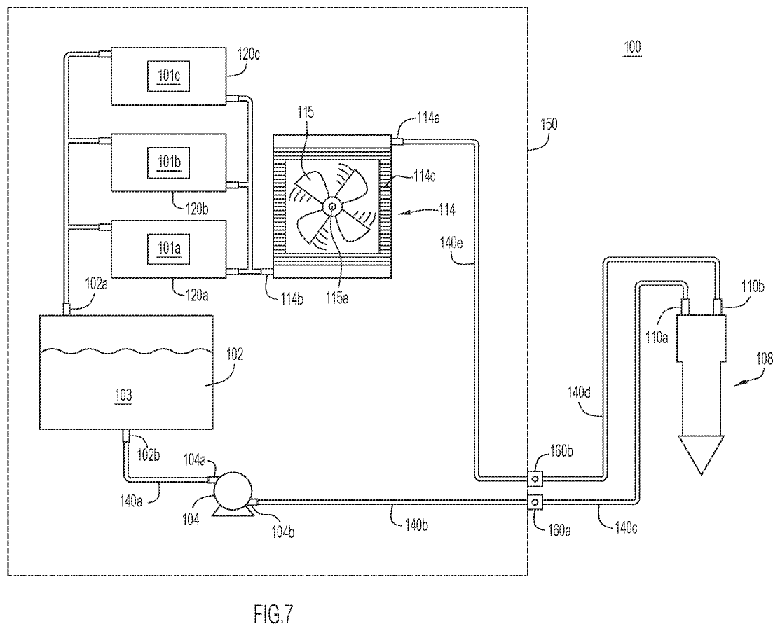

The system of FIG. 7 differs from the system of FIG. 6 in that the cooling plates 120a, 120b and 120c are disposed in parallel to one another in terms of coolant flow instead of being arranged in series.

As shown in FIGS. 6 and 7, according to some implementations the torch 108 and associated fluid conduits 140c and 140d are located outside a housing 150 in which the remainder of the components are located. According to such an implementation, the conduits 140c and 140d are respectively coupled to conduits 140b and 140e by coupling devices 160a and 160b that protrude from or extend through a wall of the housing 150. According to some implementations the coupling devices 160a and 160b are quick connect couplers.

The terms “upstream” and “downstream” are used throughout this disclosure to indicate the relative position of system components in regard to the direction of the fluid flow. The term “downstream” indicates a position in a direction of fluid flow and “upstream” indicates a position in a direction opposite the fluid flow.

As noted above, according to some implementations the heat exchanger 114 is a radiator having a cooling fan 115 that forces air over the radiator coils 114c that carry the fluid 103. The cooling fan 115 is driven by an electric motor 115a that according to some implementations is governed by a controller 220. According to some implementations the controller 220 is configured to cause the motor 115a of the fan 115 to turn on and off in response to one or more of the temperature signals 171a, 171b and 171c. According to other implementations, the cooling fan motor 115a is a variable speed motor and the controller 220 configured to alter the speed of the motor in response to one or more of the temperature sensor signals 171a, 171b and 171c.

According to some implementations, the pump 104 is driven by an electric motor 104c and the controller is configured to turn the pump motor on and off based on temperature signals 171a, 171b and 171c. According to other implementations, the motor 104c is a variable speed electric motor and the controller 220 is configured alter the speed of the motor based on temperature signals 171a, 171b and 171c.

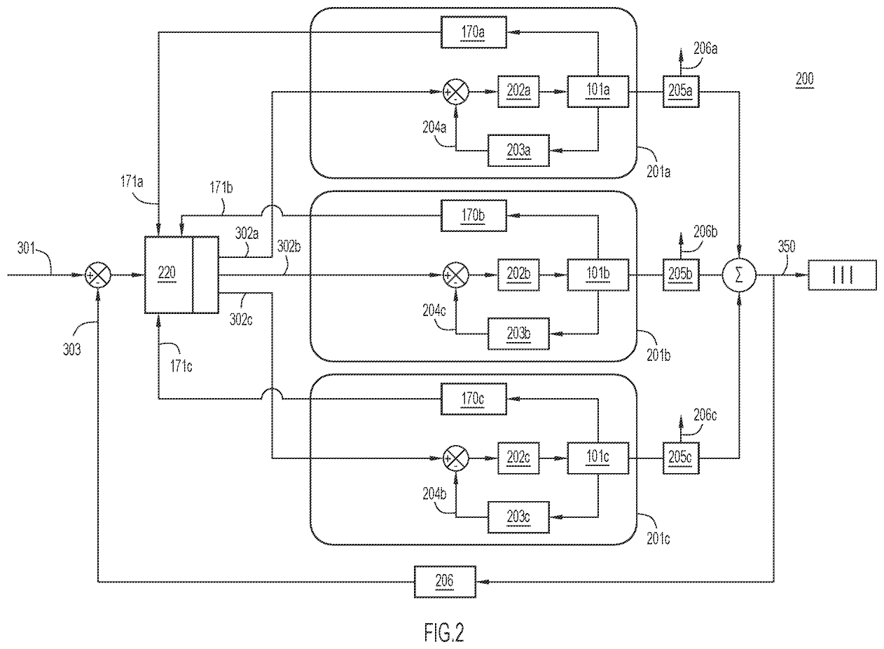

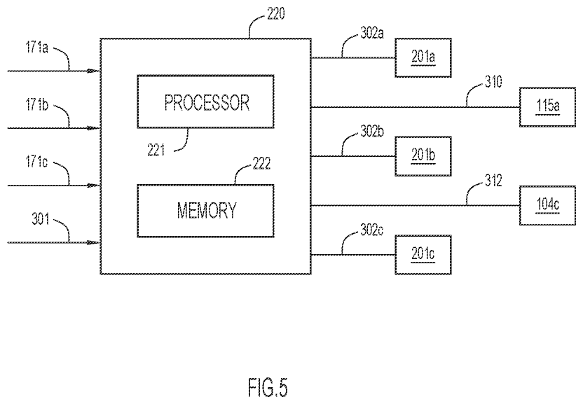

According to some implementation, as shown in FIG. 5, the controller 220 that operates motor 115a and/or motor 104c forms a part of a control circuit 200. The control circuit 200 is depicted in FIG. 2 and will be discussed in more detail below. According to some implementations, the controller 220 comprises at least one processor 221 and at least one memory 222 for storing instructions to be implemented/executed by the processor. According to one implementation, the controller 220 generates output signals 310 and/or 312 that directly or indirectly influence the operation of one or both of the fan motor 115a and the pump motor 104c based temperature signals 171a, 171b and 171c received by the controller. In this manner, the IGBT junction temperatures may be managed in part by regulating one or both of fan 115 and pump 104. According to some implementations, the controller 220 is configured to control the open and closed position of switches that control the delivery of power to motors 104c and 115a.

As will be explained in more detail below and as depicted in FIG. 5, the controller 220 may be configured to control one or both of motors 104c and 115a concurrently with controlling the flow of current to inverters 201a, 201b and 201c.

As disclosed above, disclosed herein are systems and methods for lessening/reducing temperature differences among IGBTs residing in different inverters to minimize the occurrence of thermal trips during plasma torch operation. Thus, when a thermal trip condition occurs, it is when most or all of the IGBTs of the inverters are approaching or have reached a threshold trip temperature.

FIG. 2 is a control diagram for regulating current flows through multiple inverters 201a, 201b and 201c for the purpose of lessening differences between measured temperatures of IGBTs 101a, 101b and 101c comprised in the inverters. The regulating of the current flows occurs while the inverters 201a, 201b and 201c collectively deliver a current 350 to the torch electrode 111. In some instances, current flow regulation to the inverters may be based on the measured IGBT temperatures. For example, the IGBT temperatures may be measured by temperature sensors 170a. 170b and 170c attached to or coupled to a casing 20 of an IGBT (as discussed above), or to a lug or other thermally conductive part of the IGBTs. In other instances, current flow regulation to the inverters may be based on IGBT junction temperatures empirically determined using the actual measured temperatures.

In the implementation of FIG. 2, current flow through each of the inverters 201a, 201b and 201c is regulated by a controller 220 that receives a current request signal 301 that is indicative of an amount of current requested to be delivered to the torch electrode 111. According to some implementations, the circuit 200 includes current feedback control in which a current sensor 206 monitors the current 350 delivered to the electrode 111 and generates a signal 303 that is compared with the original current request signal 301. According to some implementations, the current feedback signal 303 is received by the controller 220 where it is compared with the current request signal 301 to determine if the control circuit is operating properly. According to some implementations, when the current 350 delivered to the torch electrode is not consistent with the original current request signal 301, the current request signal 301 may be altered to cause an intended amount of current to be delivered to the electrode.

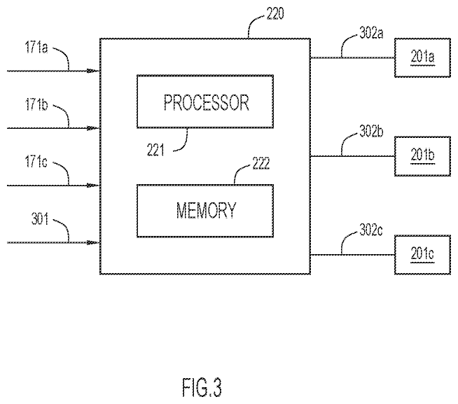

As shown in FIG. 2 and FIG. 3, in response to the current request signal 301 and temperature signals 171a, 171b, 171c, the controller 220 is configured to generate output signals 302a, 302b and 302c that are respectively used to control current flows generated by inverters 201a, 201b and 201c. In particular, the controller 220 is configured to regulate a first flow of current through the first inverter 201a, a second flow of current through the second inverter 201b, and a third flow of current through the third inverter 201c based on input signals 301, 171a, 171b and 171c. The controller 220 is configured, through the instructions stored in memory 222 and executed by the processor 221, to regulate the first flow of current, the second flow of current and the third flow of current to lessen differences between at least two of the first sensed temperature of IGBT 101a, the second sensed temperature of IGBT 101b, and the third sensed temperature of IGBT 101c while the first, second and third flows of current are being respectively delivered through the first, second and third inverters to the torch electrode 111. This involves measuring a temperature of each of the IGBTs 101a, 101b and 101c, and thereafter altering the flow of current through one or more of the IGBTs 101a, 101b and 101c based on the differences in the measured temperatures of the IGBTs. For example, when the first sensed temperature is greater than each of the second and third sensed temperatures, the controller 220 is configured to decrease the first flow of current through the first inverter 201a and/or increase one or both of the second flow of current through the second inverter 201b and the third flow of current through the third inverter 201c.

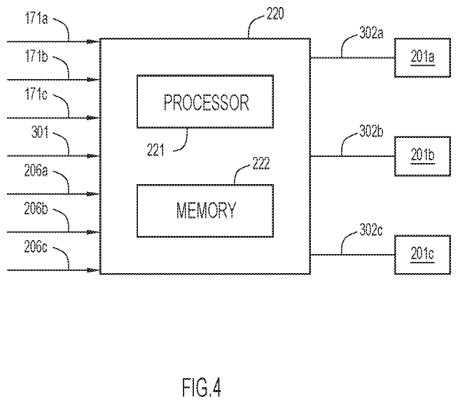

As shown in FIG. 2 and FIG. 4, according to some implementations, current flows through the inverters are controlled for the purpose of lessening temperature differences between the IGBTs 101a, 101b and 101c by the controller 220 additionally taking into account sensed current outputs of the inverters 201a, 201b and 201c. According to some implementations this is achieved through the use of current sensors 205a, 205b and 205c that are respectively arranged to measure a current output of inverters 201a, 201b and 201c and to produce current signals 206a, 206b and 206c that are input to the controller 220.

As illustrated in FIG. 2, PID (proportional-integral-derivative) controllers 202a, 202b and 202c that are respectively associated with IGBTs 101a, 101b and 101c, provide a control loop mechanism employing feedback to ensure the IGBTs 101a, 101b and 101c are generating current flows consistent with current flow instructions embodied in the controller output signals 302a, 302b and 302c. In doing so, output signals 204a, 204b and 204c generated by IGBT current sensors 203a, 203b and 203c are compared with current request signals 302a, 302b and 302c outputted by controller 320.

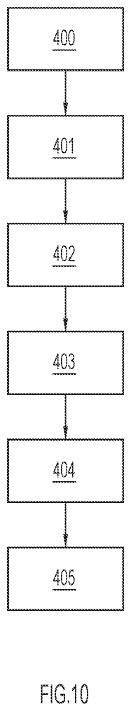

FIG. 10 is a flow chart of a method for delivering current to a torch electrode using at least first and second inverters for the purpose of producing a plasma arc, each of the first and second inverters include one or more IGBTs, the first inverter including a first IGBT, the second inverter including a second IGBT. At step 400, first and second temperature sensors are used to respectively sense a temperature of the first and second IGBTs. At step 401, first and second temperature signal indicative of the sensed temperatures of the first and second IGBTs are produced. At step 402, receiving a current request signal indicative of an amount of current requested to be delivered to the electrode. At step 403, regulating a first flow of current through the first inverter and regulating a second flow of current through the second inverter based on the respective first and second temperature signals and the current request signal. At step 404, using the first and second temperature signals and the current request signal to regulate one or both of the first flow of current and the second flow of current to lessen a difference between the temperature of the first IGBT and the temperature of the second IGBT while the first and second flow of current are being respectively delivered through the first and second inverters. At step 405, when the temperature of the second IGBT is greater than the temperature of the first IGBT, increasing the first flow of current through the first inverter and/or decreasing the second flow of current through the second inverter.

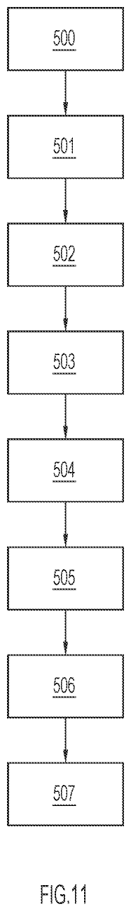

FIG. 11 is a flow chart of a method for delivering current to a torch electrode using at least first and second inverters for the purpose of producing a plasma arc, each of the first and second inverters include one or more IGBTs, the first inverter including a first IGBT, the second inverter including a second IGBT. At step 500, first and second temperature sensors are used to respectively sense a temperature of the first and second IGBTs. At step 501, first and second temperature signal indicative of the sensed temperatures of the first and second IGBTs are produced. At step 502, first and second current sensors are respectively used to sense a current produced by the first inverter and a current produced by the second inverter. At step 503, first and second current signals indicative of the currents respectively produced by the first and second inverters are produced. At step 504, receiving a current request signal indicative of an amount of current requested to be delivered to the electrode. At step 505, regulating a first flow of current through the first inverter and regulating a second flow of current through the second inverter based on the respective first and second temperature signals, first and second current signals, and the current request signal. At step 506, using the first and second temperature signals, first and second current signals and the current request signal to regulate one or both of the first flow of current and the second flow of current to lessen a difference between the temperature of the first IGBT and the temperature of the second IGBT while the first and second flow of current are being respectively delivered through the first and second inverters. At step 507, when the temperature of the second IGBT is greater than the temperature of the first IGBT, increasing the first flow of current through the first inverter and/or decreasing the second flow of current through the second inverter.

The systems and methods disclosed herein are aimed at reducing the temperature differences between IGBTs residing in different inverters while the inverters are used to deliver current to a torch electrode. In the foregoing description, various parameters are disclosed as being at least partially determinative of the how current flow rates to multiple inverters are managed to achieve this objective. These parameters include one or more of sensed temperatures of the IGBTs, sensed output currents of the inverters, and a current request signal. It is appreciated, however, that other parameters and control schemes may be additionally used to achieve the aforesaid objective.

What is claimed is:

1. A system comprising:
first and second inverters that are collectively configured to deliver current to an electrode of a torch for the purpose of producing a plasma arc, each of the first and second inverters respectively including one or more IGBTs, the first inverter including a first IGBT and the second inverter including a second IGBT; and
a power control system that is configured to regulate a first flow of current through the first inverter and to regulate a second flow of current through the second inverter based on a first current request signal, at least a first sensed temperature of the first IGBT and at least a second sensed temperature of the second IGBT, the power control system including a controller configured to receive the first current request signal, a first temperature signal indicative of the first sensed temperature, and a second temperature signal indicative of the second sensed temperature, the controller being configured to regulate the first flow of current and the second flow of current to lessen a difference between the first sensed temperature and the second sensed temperature while the first and second flow of current are being respectively delivered through the first and second inverters.

2. The system according to claim 1, wherein when the second sensed temperature is greater than the first sensed temperature, the controller is configured to increase the first flow of current through the first inverter and/or decrease the second flow of current through the second inverter.

3. The system according to claim 1, wherein the power control system further includes:
first and second current sensors that are respectively configured to produce first and second current signals indicative of first and second currents produced by the first and second inverters, the controller being configured to receive the first current signal and the second current signal, the controller also being configured to regulate the first flow of current through the first inverter and the second flow of current through the second inverter based at least in part on the first current signal and the second current signal.

4. The system according to claim 1, wherein the first and second IGBTs are respectively thermally coupled to first and second cooling plates, each of the first and second cooling plates being thermally coupled to tubing through which a fluid is configured to flow to respectively regulate the temperature of the first and second IGBTs, the fluid being circulated through a cooling system that includes a heat exchanger through which the fluid passes for the purpose of being cooled, the heat exchanger having a fluid outlet through which the fluid is delivered to the tubing, the first and second cooling plates being disposed in series with the second cooling plate being located downstream the first cooling plate.

5. The system according to claim 1, wherein the first and second IGBTs are respectively thermally coupled to first and second cooling plates, each of the first and second cooling plates being respectively thermally coupled to first and second tubing through which a fluid is configured to flow to respectively regulate the temperature of the first and second IGBTs, the fluid being circulated through a cooling system that includes a heat exchanger through which the fluid passes for the purpose of being cooled, the heat exchanger having a fluid outlet through which the fluid is delivered to the first and second tubing, the first and second tubing being disposed in parallel with one another.

6. The system according to claim 1, wherein the power control system is configured to regulate the first flow of current through the first inverter and to regulate the second flow of current through the second inverter also based on a second current request signal, the first and second current request signals respectively supporting first and second modes of operation of the torch.

7. The system according to claim 6, wherein the controller is also configured to regulate the first flow of current and the second flow of current to lessen a difference between the first sensed temperature and the second sensed temperature while the first and second flows of current are being respectively delivered through the first and second inverters based on the second current request signal associated with the second mode of operation of the torch, the second mode of operation of the torch requiring more or less current to be delivered to the torch electrode than the first mode of operation of the torch.

8. The system according to claim 1, wherein the first sensed temperature is sensed by a first temperature sensor attached to or coupled to a casing of the first IGBT and the second sensed temperature is sensed by a second temperature sensor attached to or coupled to a casing of the second IGBT.

9. The system according to claim 4, wherein the heat exchanger is a radiator having a cooling fan that is driven by a motor, the controller being configured to cause the motor of the fan to turn on and off in response to one or both of the first and second sensed temperatures.

10. The system according to claim 4, wherein the heat exchanger is a radiator having a cooling fan that is driven by a variable speed motor, the controller being configured to alter the speed of the variable speed motor of the fan in response to one or both of the first and second sensed temperatures.

11. The system according to claim 4, wherein the cooling system includes a pump that is configured to circulate the fluid through the cooling system, the pump is driven by a motor, the controller being configured to cause the motor of the pump to turn on and off in response to one or both of the first and second sensed temperatures.

12. The system according to claim 4, wherein the cooling system includes a pump that is configured to circulate the fluid through the cooling system, the pump is driven by a variable speed motor, the controller being configured to alter the speed of the variable speed motor of the pump in response to one or both of the first and second sensed temperatures.

13. The system according to claim 4, further comprising the torch in which the electrode resides, the cooling system including a pump that is configured to circulate the fluid through the cooling system, the torch having a cooling channel through which the fluid is configured to flow to cool the electrode, the pump having a fluid outlet located upstream and in fluid communication with a fluid inlet of the cooling channel, the heat exchanger having a fluid inlet located downstream and in fluid communication with a fluid outlet of the torch cooling channel.

14. A system comprising:
first and second and third inverters that are collectively configured to deliver current to an electrode of a torch for the purpose of producing a plasma arc, each of the first, second and third inverters including one or more IGBTs, the first inverter including a first IGBT, the second inverter including a second IGBT, the third inverter including third IGBT;
a power control system that is configured to regulate a first flow of current through the first inverter, to regulate a second flow of current through the second inverter and to regulate a third flow of current through the third inverter based on a current request signal, at least a first sensed temperature of the first IGBT, at least a second sensed temperature of the second IGBT, and at least a third sensed temperature of the third IGBT, the power control system including a controller configured to receive the first current request signal, a first temperature signal indicative of the first sensed temperature, a second temperature signal indicative of the second sensed temperature, and a third temperature signal indicative of the third sensed temperature, the controller being configured to regulate the first flow of current, the second flow of current and the third flow of current to lessen differences between the first sensed temperature, the second sensed temperature and third sensed temperature while the first, second and third flows of current are being respectively delivered through the first, second and third inverters.

15. The system according to claim 14, wherein when the first sensed temperature is greater than each of the second and third sensed temperatures, the controller is configured to decrease the first flow of current through the first inverter and/or increase one or both of the second flow of current through the second inverter and the third flow of current through the third inverter.

16. The system according to claim 14, wherein the power control system further includes:
first, second and third current sensors that are respectively configured to produce first, second and third current signals indicative of first, second and third currents produced by the first, second and third inverters, the controller being configured to receive the first, second and third current signals, the controller also being configured to regulate the first flow of current through the first inverter, the second flow of current through the second inverter, and the third flow of current through the third inverter based at least in part on the first, second and third current signals.

17. The system according to claim 14, wherein the first, second and third IGBTs are respectively thermally coupled to first, second and third cooling plates, each of the first, second and third cooling plates being thermally coupled to tubing through which a fluid is configured to flow to respectively regulate the temperature of the first, second and third IGBTs, the fluid being circulated through a cooling system that includes a heat exchanger through which the fluid passes for the purpose of being cooled, the heat exchanger having a fluid outlet through which the fluid is delivered to the tubing, the first, second and third cooling plates being disposed in series with the second cooling plate being located downstream the first cooling plate and the third cooling plate being located downstream the second cooling plate.

18. A method for delivering current using at least first and second inverters to an electrode of a torch for the purpose of producing a plasma arc, each of the first and second inverters including one or more IGBTs, the first inverter including a first IGBT, the second inverter including a second IGBT, the method comprising:
using a first temperature sensor to sense a temperature of the first IGBT and producing a first temperature signal indicative of the temperature of the first IGBT;
using a second temperature sensor to sense a temperature of the second IGBT and producing a second temperature signal indicative of the temperature of the second IGBT;
receiving a current request signal indicative of an amount of current requested to be delivered to the electrode;
regulating a first flow of current through the first inverter and regulating a second flow of current through the second inverter based on the respective first and second temperature signals and the current request signal;
using the first and second temperature signals and the current request signal to regulate one or both of the first flow of current and the second flow of current to lessen a difference between the temperature of the first IGBT and the temperature of the second IGBT while the first and second flow of current are being respectively delivered through the first and second inverters.

19. The method according to claim 18, wherein when the temperature of the second IGBT is greater than the temperature of the first IGBT, increasing the first flow of current through the first inverter and/or decreasing the second flow of current through the second inverter.

20. The method according to claim 18, further comprising:
using a first current sensor to sense a current produced by the first inverter and to produce a first current signal indicative of the current produced by the first inverter;
using a second current sensor to sense a current produced by the second inverter and to produce a second current signal indicative of the current produced by the second inverter;
regulating one or both of the first flow of current through the first inverter and the second flow of current through the second inverter using the first current signal and the second current signal.
